(19) United States
(12) Patent Application Publication
(10) Pub. No.: US 2017/0298496 A1
(43) Pub. Date: Oct. 19, 2017

(54) METAL MASK COOLING DEVICE AND METAL MASK EVAPORATING DEVICE

(71) Applicant: BOE TECHNOLOGY GROUP CO., LTD., Beijing (CN)

(72) Inventor: Yuan-Ming Chiang, Beijing (CN)

(73) Assignee: BOE TECHNOLOGY GROUP CO., LTD., Beijing (CN)

(21) Appl. No.: 15/513,128

(22) PCT Filed: Mar. 1, 2016
(86) PCT No.: PCT/CN2016/075136

§ 371 Date: Mar. 21, 2017

(30) Foreign Application Priority Data
Sep. 23, 2015 (CN) 201510612416.3

(51) Int. Cl. C23C 14/04; C23C 14/24; H01L 51/00; H01L 35/32; H01L 51/56

(52) U.S. Cl. CPC C23C 14/042; C23C 14/24; H01L 51/0011; H01L 35/32; H01L 51/56; H01L 51/001

(57) ABSTRACT

Embodiments of the present invention relate to the field of active matrix displaying, and particularly to a metal mask cooling device and a metal mask evaporating device. The metal mask cooling device includes: a cooler, a power controlling unit, an electric power supply unit and a magnetic plate, wherein, the cooler is attached to one side surface of a substrate. Under the action of the magnetic plate, the cooler and the metal mask are absorbed onto both side surfaces of the substrate, respectively. By controlling operation of the cooler by means of the power controlling unit, the cooler cools down the metal mask. The cooler and the power controlling unit are supplied with electric power by the electric power supply unit.

### BACKGROUND

### 1. Technical Field

Embodiments of the present invention relate to the field of active matrix displaying, and particularly to a metal mask cooling device and a metal mask evaporating device.

### 2. Description of the Related Art

In the manufacturing process of an OLED (Organic light-emitting diode), many ways may be adopted for patterning technology of organic electroluminescence materials. However, vacuum evaporation plus metal mask method is currently adopted as one main way in mass production. This way of patterning organic electroluminescence materials is adopted by most of manufacturers since it can achieve well screen efficiency. In this way of patterning, a metal mask is disposed to one side surface of a glass substrate, while material is evaporated by an evaporation source to be deposited on the glass substrate. In the process of the evaporation, the glass substrate and the metal mask are caused to be risen in temperature (generally with a temperature-rising difference of about 10° C.˜30° C.), thereby making the metal mask be deformed in its position and structure due to rising of the temperature. In the process of production, deviation of positional precision caused by the deformation in the position and structure will result in color-mixing defect of the screen. As a result, it is great important how to ensure the quality of the metal mask so as to avoid color-mixing defect of the screen caused by the deviation of positional precision in the process of production. At present, in the art, generally necessary measures are adopted to control temperature of the metal mask, in order to ensure the quality of the metal mask.

### SUMMARY

According to one aspect of embodiments of the present invention, there is provided a metal mask cooling device, comprising: a cooler, a power controlling unit, an electric power supply unit and a magnetic plate, wherein, the cooler is attached to one side surface of a substrate, to cool, via the substrate, a metal mask attached to the other side surface of the substrate; a magnetic plate is disposed on the cooler, to absorb the cooler and the metal mask onto both side surfaces of the substrate, respectively; the power controlling unit is connected to the cooler, for controlling a cooling temperature of the cooler; and, the electric power supply unit is connected respectively to the cooler and the power controlling unit, for supplying electric power to the cooler and the power controlling unit.

In some embodiments, the cooler may comprise a semiconductor cooler.

In some embodiments, the semiconductor cooler comprises an N-type semiconductor and a P-type semiconductor corresponding to each other.

In some embodiments, the metal mask cooling device may further comprises a heat radiating unit disposed on a heat-generating side surface of the cooler.

In some embodiments, the heat radiating unit may comprise a heat radiating copper sheet attached to the heat-generating side surface of the cooler and a plurality of copper heat radiating tubes connected vertically to the heat radiating copper sheet.

According to another aspect of embodiments of the present invention, there is provided a metal mask evaporating device comprising an evaporating room and, the abovementioned metal mask cooling device disposed within the evaporating room.

In some embodiments, a substrate position adjusting unit and a substrate position observing unit may be disposed on a top of the evaporating room.

In some embodiments, a vacuum-pumping unit may be disposed on a side of the evaporating room.

In some embodiments, an evaporating gas generation unit may be disposed on a bottom of the evaporating room.

### BRIEF DESCRIPTION OF THE DRAWINGS

FIG. 1 is a structural schematic view of a laminated metal cooling plate in a conventional water-cooling technology;

FIG. 2 is a structural schematic view showing mounting of a heat sink in a metal mask cooling device according to an embodiment of the present invention;

FIG. 3 is a schematic view showing connection relationship among some components in a metal mask cooling device according to an embodiment of the present invention;

FIG. 4 is a structural schematic view of a metal mask evaporating device according to an embodiment of the present invention; and

FIG. 5 is a structural schematic view of a portion A in FIG. 4, showing the metal mask cooling device according to the embodiment of the present invention.

### DETAILED DESCRIPTION OF THE EMBODIMENTS

Embodiments of the present invention will be further described hereinafter in detail and completely with reference to the attached drawings. These embodiments are merely used to illustrate and explain the present invention, but not to limit the present invention.

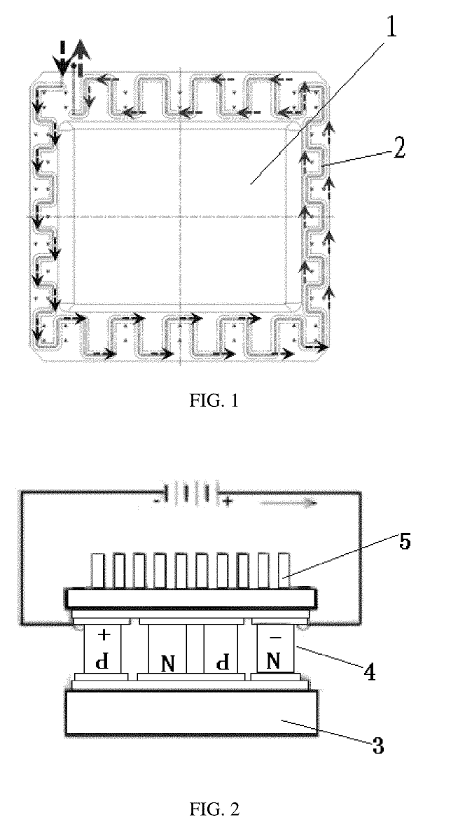

At present, referring to FIG. 1, a way of cooling by cooling water is mainly adopted for controlling a temperature of an evaporation metal mask in manufacturing the OLED (Organic light-emitting diode) in mass production. Cooling water pipeline is mounted at a glass substrate side of an evaporation metal mask plate within a chamber, particularly within a laminated metal plate. When an evaporation process is implemented, the metal mask plate, the glass substrate and the laminated metal cooling plate 1 (with the cooling water pipeline 2 disposed therein) are attached to one another. Amount of heat caused by the temperature-rising of the metal mask plate is brought by the low-temperature cooling water, which reduces a possibility of deforming the metal mask plate by being heated, and maintains stabilities of the metal mask plate and the glass substrate during a high-temperature evaporation process. However, for this way of cooling, because it is inconvenient to mount the cooling water pipeline, as well as because of layout of the cooling water pipeline, distribution uniformity of the temperature between the metal mask plate and the glass substrate easily gets worse. Further, a response time of controlling the water cooling temperature is slow due to great thermal inertial. Furthermore, the cooling water pipeline is prone to be clogged over time and the maintenance is not easy.

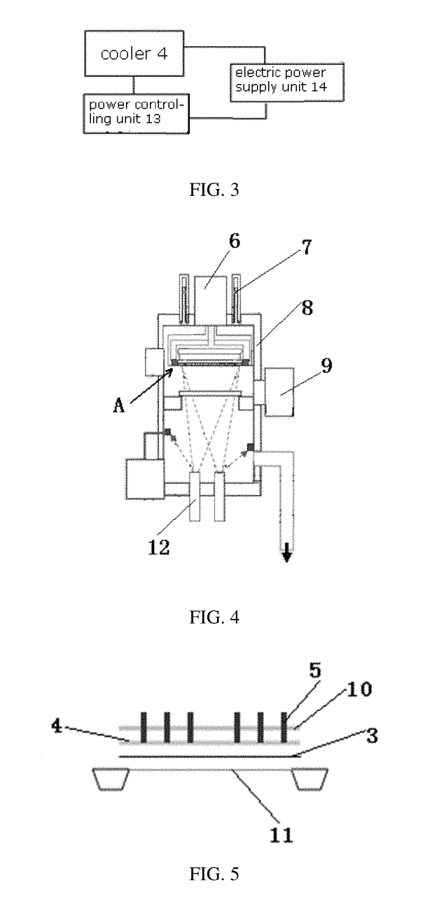

Referring to FIG. 2, FIG. 3 and FIG. 5, a metal mask cooling device according to an embodiment of the present invention comprises a cooler 4, a power controlling unit 13, an electric power supply unit 14 and a magnetic plate 10. The cooler 4 is attached to one side surface of the substrate 3, to cool, via the substrate 3, a metal mask 11 attached to the other side surface of the substrate 3. The magnetic plate 10 is disposed on the cooler 4, to absorb the cooler 4 and the metal mask 11 onto both side surfaces of the substrate 3, respectively. The power controlling unit 13 is connected to the cooler 4, for controlling a cooling temperature of the cooler 4. The electric power supply unit 14 is connected respectively to the cooler 4 and the power controlling unit 13, for supplying electric power to the cooler 4 and the power controlling unit 13. The cooler 4 is preferably a semiconductor cooler.

In the abovementioned embodiment, the cooler 4 is attached to one side surface of the substrate 3 and, under the action of the magnetic plate 10, the cooler 4 and the metal mask 11 are absorbed onto both side surfaces of the substrate 3, respectively. By controlling operation of the cooler 4 by means of the power controlling unit 13, the cooler 4 cools down the metal mask 11. The cooler 4 and the power controlling unit 13 are supplied with electric power by the electric power supply unit 14. With the above configuration, by utilization of thermoelectric principle, the metal mask 11 attached to the other side surface of the substrate 3 is cooled down by the cooler 4 attached to one side surface of the substrate 3, so that the metal mask 11 everywhere will be cooled down evenly, thereby eliminating deformation in its structure and position. Meanwhile, since operation of the cooler 4 is controlled by the power controlling unit 13, there achieves temperature controlling in time, smaller thermal inertial, higher temperature-controlling efficiency. In addition, adoption of the cooler 4 facilitates the mounting and maintenance and prolongs the service life.

A semiconductor cooler is used preferably as the cooler 4, mainly because it may have the following advantages when being applied in technique.

No coolant is needed and a continuous operation can be obtained. No rotational effect will be generated since there is neither a pollution source nor a rotating component. Instead of a sliding component, there is a solid state component which has no vibration and noise in operations and has prolonged service life and is easy to mount.

The semiconductor cooler has both a refrigeration function and a heating function, accordingly, a heating system and a refrigeration system separate from each other are replaced by a single component.

The semiconductor cooler is a current energy transducing type component by mean of which a high precision temperature control can be achieved by controlling an input current. With the help of a temperature detecting and controlling measure, it is easy to obtain a computer control and to form an automatically controlling system.

The semiconductor cooler has an extremely small thermal inertial and a rapid refrigerating/heating time, accordingly, in a case that its hot end is good in thermal radiation while its cold end is idle, the cooler can achieve a maximum temperature difference after being electrically energized for less than a minute.

The semiconductor cooler can achieve a great range of adjustment temperature difference, generally, temperature induced by a semiconductor cooler has a range from positive 90° C. to negative 130° C. (130° C. below zero).

Specifically, the semiconductor cooler 4 comprises an N-type semiconductor and a P-type semiconductor corresponding to each other.

Moreover, referring to FIG. 5, the metal mask cooling device according to an embodiment of the present invention further comprises a heat radiating unit 5 disposed on a heat-generating side surface of the cooler 4. It can speed up heat radiation on the heat-generating side surface of the cooler 4, thereby increasing cooling-down efficiency of the cooler 4.

Specifically, the heat radiating unit 5 comprises a heat radiating copper sheet attached to the heat-generating side surface of the cooler 4 and a plurality of copper heat radiating tubes connected vertically to the heat radiating copper sheet. Copper material is used because of its good thermal conductivity performance, and copper heat radiating tubes are used to enhance heat radiating effect.

Referring to FIG. 4, according to another aspect of the present invention, there provides a metal mask evaporating device comprising an evaporating room 8 and the abovementioned metal mask cooling device, wherein, the metal mask cooling device is disposed within the evaporating room 8.

Generally, a substrate position adjusting unit 6 and a substrate position observing unit 7, for observing and adjusting position of the substrate 3 thereby achieving an accurate alignment to the metal mask 11, are disposed on a top of the evaporating room 8. A vacuum-pumping unit 9 for achieving an evaporation process in a vacuum environment is disposed on a side of the evaporating room 8. An evaporating gas generation unit 12 for generation of evaporating gas is disposed on a bottom of the evaporating room 8.

Concerning the above, in the metal mask cooling device and the metal mask evaporating device provided by the present invention, the cooler 4 is attached to one side surface of the substrate 3, and, under the action of the magnetic plate 10, the cooler 4 and the metal mask 11 are absorbed onto both side surfaces of the substrate 3, respectively. By utilization of thermoelectric principle, the metal mask 11 is cooled down by the cooler 4, so that the metal mask 11 everywhere will be cooled down evenly, thereby eliminating deformation in its position and structure. Meanwhile, since operation of the cooler 4 is controlled by the power controlling unit 13, there achieves temperature controlling in time, smaller thermal inertial, higher temperature-controlling efficiency. In addition, adoption of the cooler 4 facilitates the mounting and maintenance and prolongs the service life.

The above description is merely used to illustrate preferable embodiments of the present invention. It should be understood by those skilled in the art that, all of changes and modifications made easily within principles and spirit of the present invention should be included within the scope of the present invention.

1. A metal mask cooling device, comprising: a cooler, a power controlling unit, an electric power supply unit and a magnetic plate, wherein, the cooler is attached to one side surface of a substrate, to cool, via the substrate, a metal mask attached to the other side surface of the substrate; a magnetic plate is disposed on the cooler, to absorb the cooler and the metal mask onto both side surfaces of the substrate, respectively; the power controlling unit is connected to the cooler, for controlling a cooling temperature of the cooler; and, the electric power supply unit is connected respectively to the cooler and the power controlling unit, for supplying electric power to the cooler and the power controlling unit.

2. The metal mask cooling device of claim 1, wherein, the cooler comprises a semiconductor cooler.

3. The metal mask cooling device of claim 2, wherein, the semiconductor cooler comprises an N-type semiconductor and a P-type semiconductor corresponding to each other.

4. The metal mask cooling device of claim 1, further comprising a heat radiating unit disposed on a heat-generating side surface of the cooler.

5. The metal mask cooling device of claim 4, wherein, the heat radiating unit comprises a heat radiating copper sheet attached to the heat-generating side surface of the cooler and a plurality of copper heat radiating tubes connected vertically to the heat radiating copper sheet.

6. A metal mask evaporating device comprising an evaporating room and, the metal mask cooling device of claim 1, disposed within the evaporating room.

7. The metal mask evaporating device of claim 6, wherein, a substrate position adjusting unit and a substrate position observing unit are disposed on a top of the evaporating room.

8. The metal mask evaporating device of claim 6, wherein, a vacuum-pumping unit is disposed on a side of the evaporating room.

9. The metal mask evaporating device of claim 6, wherein, an evaporating gas generation unit is disposed on a bottom of the evaporating room.
